(19) United States
(12) Patent Application Publication
(10) Pub. No.: US 2012/0049212 A1
(43) Pub. Date: Mar. 1, 2012

(54) LED CHIP PACKAGE STRUCTURE WITH A HIGH-EFFICIENCY HEAT-DISSIPATING SUBSTRATE AND METHOD FOR MAKING THE SAME

(75) Inventors: BILY WANG, HSINCHU CITY (TW); SHIH-YU WU, TAIPEI COUNTY (TW); WEN-KUEI WU, HSINCHU COUNTY (TW)

(73) Assignee: HARVATEK CORPORATION, HSINCHU CITY (TW)

(21) Appl. No.: 13/292,376

(22) Filed: Nov. 9, 2011

Related U.S. Application Data
(62) Division of application No. 12/232,929, filed on Sep. 26, 2008.

(30) Foreign Application Priority Data
Mar. 5, 2008 (TW) 97107704

(51) Int. Cl. H01L 33/64

(52) U.S. Cl. 257/88; 257/E33.075

(57) ABSTRACT

An LED chip package structure with a high-efficiency heat-dissipating substrate includes a substrate unit, an adhesive body, a plurality of LED chips, package bodies and frame layers. The substrate unit has a positive substrate, a negative substrate, and a plurality of bridge substrates separated from each other and disposed between the positive and the negative substrate. The adhesive body is filled between the positive, the negative and the bridge substrates in order to connect and fix the positive substrate, the negative substrate and the bridge substrates together. The LED chips are disposed on the substrate unit and electrically connected between the positive substrate and the negative substrate. The package bodies are respectively covering the LED chips. The frame layers are respectively disposed around the packages bodies in order to form a plurality of light-projecting surfaces on the package bodies, and the light-projecting surfaces correspond to the LED chips.

### CROSS REFERENCE TO RELATED APPLICATION

This application is a Divisional patent application of co-pending application Ser. No. 12/232,929, filed on 26 Sep. 2008, now pending. The entire disclosure of the prior application Ser. No. 12/323,929, from which an oath or declaration is supplied, is considered a part of the disclosure of the accompanying Divisional application and is hereby incorporated by reference.

### BACKGROUND OF THE INVENTION

1. Field of the Invention

The present invention relates to an LED chip package structure and a method for making the same, and particularly relates to an LED chip package structure with a high-efficiency heat-dissipating substrate and a method for making the same.

2. Description of the Related Art

Referring to FIGS. 1 to 1B, a known method for packaging LED chips is shown. The known method includes: providing a substrate body 1a that has an insulative body 10a, a heat-dissipating layer 11a disposed under the insulative body 10a, and a positive trace 12a and a negative trace 13a disposed on the insulative body 10a (S100).

The method further includes: arranging a plurality of LED chips 2a on the substrate body 1a and electrically connecting the positive side 20a and the negative side 21a of each LED chip 2a with the positive trace 12a and the negative trace 13a of the substrate body 1a (S102); respectively covering the LED chips 2a with a plurality of fluorescent bodies 3a (S104); and then respectively disposing a plurality of opaque frame layers 4a around the fluorescent bodies 3a in order to form the light-projecting surfaces 30a on the package bodies 3a (S106).

However, because the insulative body 10a of the substrate body 1a is made of insulative material with low heat-conducting property, the heat generated by the LED chips 2a cannot be efficiently transmitted to the heat-dissipating layer 11a of the substrate body 1a to dissipate heat. Hence, the heat-dissipating efficiency of the LED chip package structure of the prior art is bad.

### SUMMARY OF THE INVENTION

The present invention provides an LED chip package structure with a high-efficiency heat-dissipating substrate and a method for making the same. The LED chip package structure of the present invention has a substrate unit that is made of high heat-conducting material and is divided into a positive substrate, a negative substrate and a plurality of bridge substrates separated from each other and disposed between the positive substrate and the negative substrate. Hence, LED chips can be directly and electrically disposed on the substrate unit in order to efficiently dissipate the heat generated from the LED chips by the substrate unit.

Furthermore, because the LED chips are arranged on a substrate body by a COB (Chip On Board) method and a hot pressing method, the manufacturing process of the LED chip package structure is simple and less time is needed for the manufacturing process. Furthermore, the LED chip package structure can be applied to any type of light source such as a back light module, a decorative lamp, a lighting lamp, or a scanner.

One aspect of the present invention is a method for making an LED chip package structure with a high-efficiency heat-dissipating substrate, comprising: providing a substrate unit that has a positive substrate, a negative substrate, and a plurality of bridge substrates separated from each other and disposed between the positive substrate and the negative substrate; filling an adhesive body between the positive substrate, the negative substrate and the bridge substrates in order to connect and fix the positive substrate, the negative substrate and the bridge substrates together; arranging a plurality of LED chips on the substrate unit, wherein the LED chips are electrically connected between the positive substrate and the negative substrate; and packaging the LED chips in order to form a plurality of light-projecting surfaces correspond to the LED chips.

Moreover, the step of packaging the LED chips further includes the following:

First embodiment is: respectively covering the LED chips with a plurality of fluorescent bodies, and then respectively disposing a plurality of frame layers around the packages bodies in order to form the light-projecting surfaces on the package bodies and the light-projecting surfaces corresponding to the LED chips. Moreover, each LED chip is a blue LED chip. Each fluorescent body is formed by mixing silicon and fluorescent powders or by mixing epoxy and fluorescent powders. In addition, each frame layer is an opaque frame layer.

Second embodiment is: respectively covering the LED chips with a plurality of transparent bodies, and then respectively disposing a plurality of frame layers around the packages bodies in order to form the light-projecting surfaces on the package bodies and the light-projecting surfaces corresponding to the LED chips. Moreover, each LED chip is used for generating white light, for example a red LED, a green LED and a blue LED are mated to generate white light. Each transparent body can be made of transparent silicon or transparent epoxy. In addition, each frame layer is an opaque frame layer.

One aspect of the present invention is an LED chip package structure with a high-efficiency heat-dissipating substrate, including: a substrate unit, an adhesive body, a plurality of LED chips, a plurality of package bodies and a plurality of frame layers.

The substrate unit has a positive substrate, a negative substrate, and a plurality of bridge substrates separated from each other and disposed between the positive substrate and the negative substrate. The adhesive body is filled between the positive substrate, the negative substrate and the bridge substrates in order to connect and fix the positive substrate, the negative substrate and the bridge substrates together. The LED chips are disposed on the substrate unit and electrically connected between the positive substrate and the negative substrate. The package bodies are respectively covering the LED chips. The frame layers are respectively disposed around the packages bodies in order to form a plurality of light-projecting surfaces on the package bodies, and the light-projecting surfaces correspond to the LED chips.

Moreover, the LED chips and the package bodies further include the following:

First embodiment is: each package body is a fluorescent body, and each LED chip is a blue LED chip. Each package body is formed by mixing silicon and fluorescent powders or by mixing epoxy and fluorescent powders.

Second embodiment is: each package body is a transparent body, and each LED chip is used for generating white light. Each transparent body is made of transparent silicon or is made of transparent epoxy.

Hence, the LED chips can be directly and electrically disposed on the substrate unit in order to efficiently dissipate the heat generated from the LED chips by the substrate unit. Furthermore, because the LED chips are arranged on a substrate body by a COB (Chip On Board) method and a hot pressing method, the manufacturing process of the LED chip package structure is simple and less time is needed for the manufacturing process.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a flowchart of a method for making an LED chip package structure of the prior art;

FIG. 1A is a top view of an LED chip package structure of the prior art;

FIG. 1B is a cross-sectional view along line 1-1 in FIG. 1A;

FIG. 2 is a flowchart of a method for making an LED chip package structure with a high-efficiency heat-dissipating substrate according to the first embodiment of the present invention;

FIGS. 2A to 2D are perspective, schematic views of an LED chip package structure with a high-efficiency heat-dissipating substrate according to the first embodiment of the present invention, at different stages of the packaging processes, respectively;

FIG. 2E is a cross-sectional view along line 2-2 in FIG. 2D;

FIG. 3 is a flowchart of a method for making an LED chip package structure with a high-efficiency heat-dissipating substrate according to the second embodiment of the present invention;

FIG. 3A is a perspective, schematic view of an LED chip package structure with a high-efficiency heat-dissipating substrate according to the second embodiment of the present invention;

FIG. 3B is a cross-sectional view along line 3-3 in FIG. 3A;

FIG. 4 is a schematic view of first type of LED chips electrically connected on a substrate unit using a wire-bonding method;

FIG. 5 is a schematic view of second type of LED chips electrically connected on a substrate unit using a wire-bonding method; and

FIG. 6 is a schematic view of third type of LED chips electrically connected on a substrate unit using a flip-chip method.

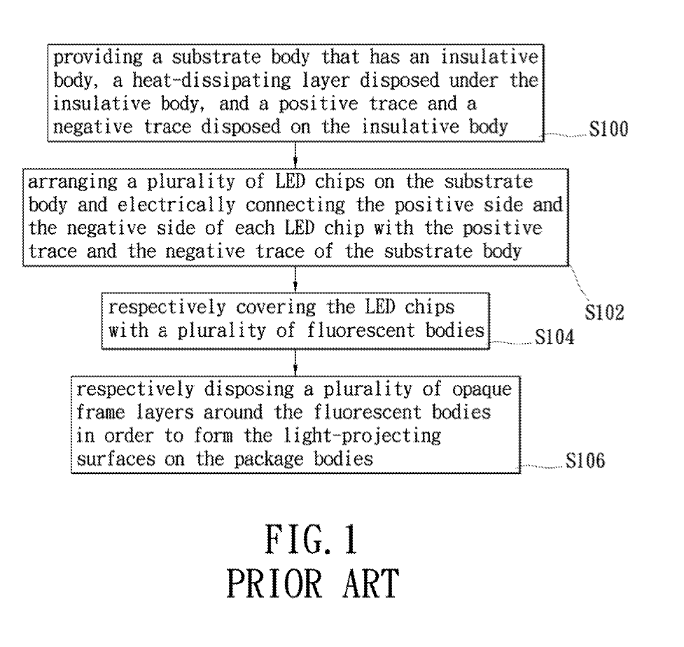

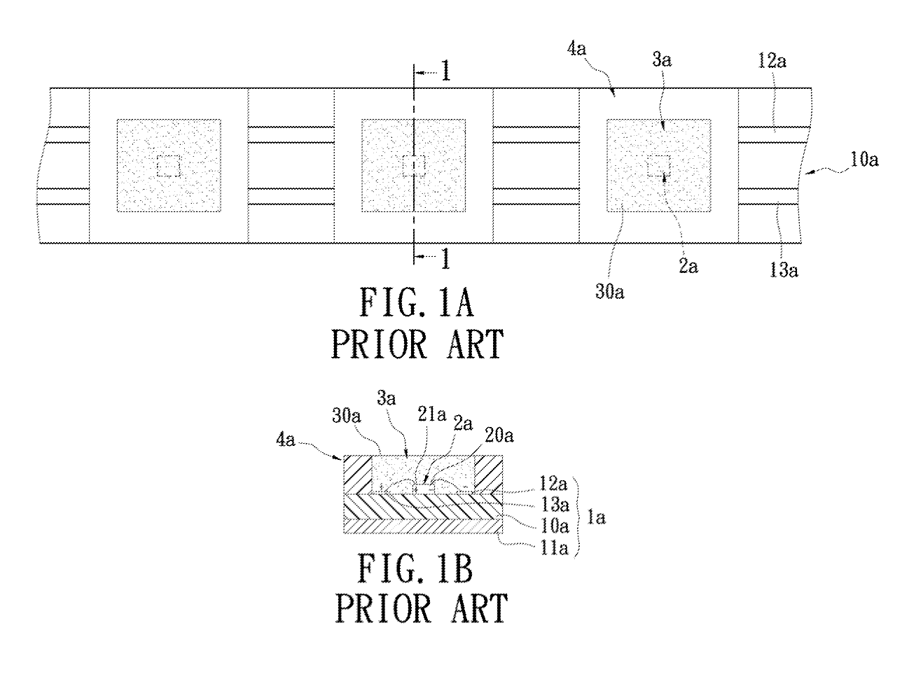

### DETAILED DESCRIPTION OF PREFERRED BEST MOLDS

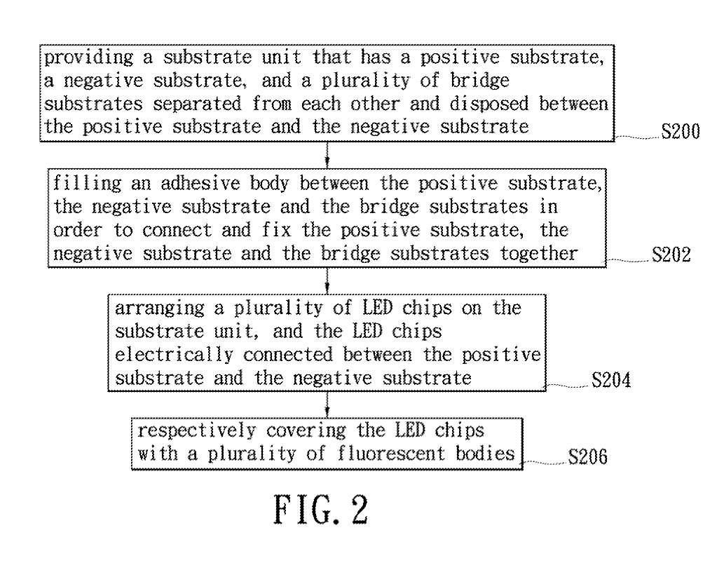

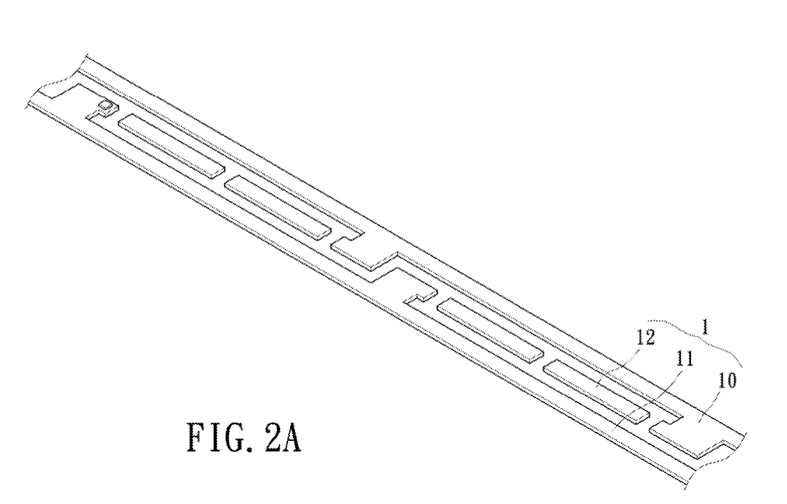

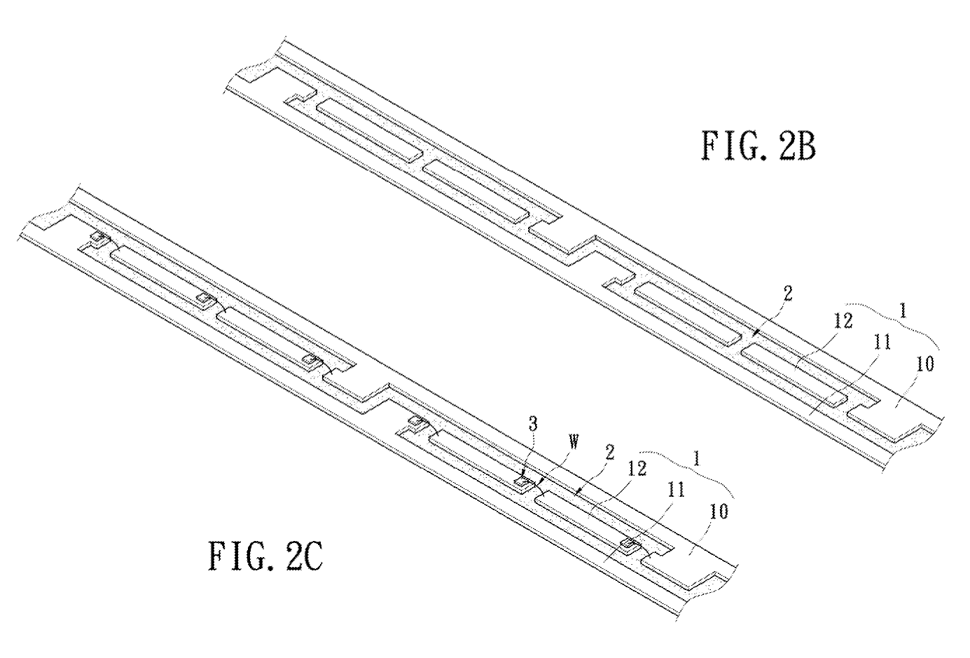

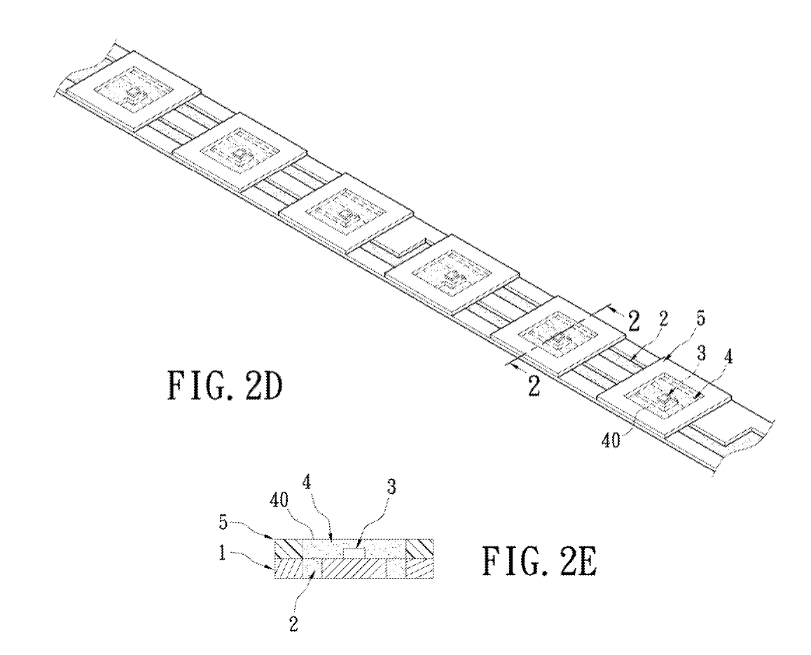

Referring to FIGS. 2, 2A to 2D, and 2E, the first embodiment of the present invention provides a method of packaging LED chips package structure with a high-efficiency heat-dissipating substrate.

The method of the present invention includes: referring to FIGS. 2 and 2A, providing a substrate unit 1 that has a positive substrate 10, a negative substrate 11, and a plurality of bridge substrates 12 separated from each other and disposed between the positive substrate 10 and the negative substrate 11 (S200). The substrate unit 1 can be a PCB (Printed Circuit Board), a flexible substrate, an aluminum substrate, a ceramic substrate, or a copper substrate.

Referring to FIGS. 2 and 2B, the method of the first embodiment further includes: filling an adhesive body 2 between the positive substrate 10, the negative substrate 11 and the bridge substrates 12 in order to connect and fix the positive substrate 10, the negative substrate 11 and the bridge substrates 12 together (S202). The adhesive body 2 can be a heat-conducting adhesive body that is made of high heat-conductive material.

Referring to FIGS. 2 and 2C, the method of the first embodiment further includes: arranging a plurality of LED chips 3 on the substrate unit 1, and the LED chips 3 electrically connected between the positive substrate 10 and the negative substrate 11 (S204). Each LED chip 3 is a blue LED chip. Each LED chip 3 is electrically connected with the positive substrate 10 and the negative substrate 11 of the substrate unit 1 via two leading wires W using a wire-bounding method.

Referring to FIGS. 2, 2D and 2E, the method of the first embodiment further includes: respectively covering the LED chips 3 with a plurality of fluorescent bodies 4 (S206), and then respectively disposing a plurality of frame layers 5 around the packages bodies 4 in order to form the light-projecting surfaces 40 on the package bodies 4 and the light-projecting surfaces 40 corresponding to the LED chips 3 (S208). Moreover, each fluorescent body is formed by mixing silicon and fluorescent powders or by mixing epoxy and fluorescent powders. In addition, each frame layer 5 is an opaque frame layer such as a white frame layer.

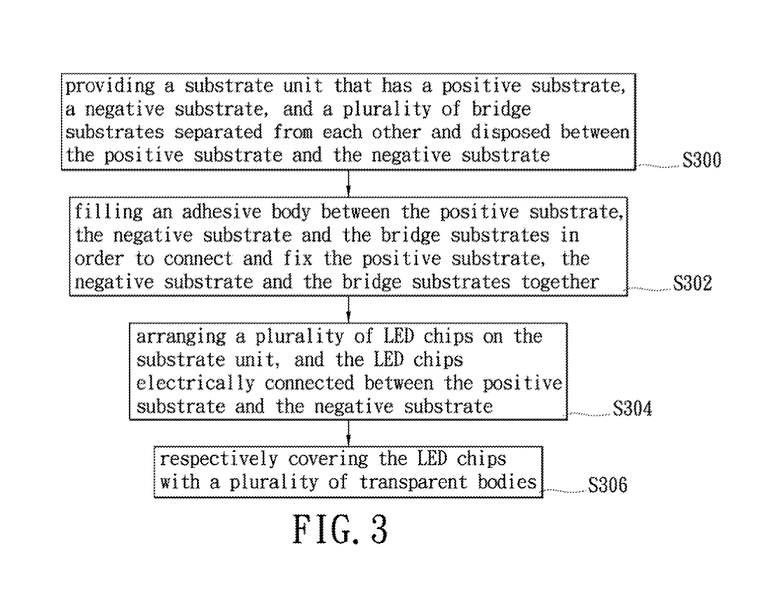

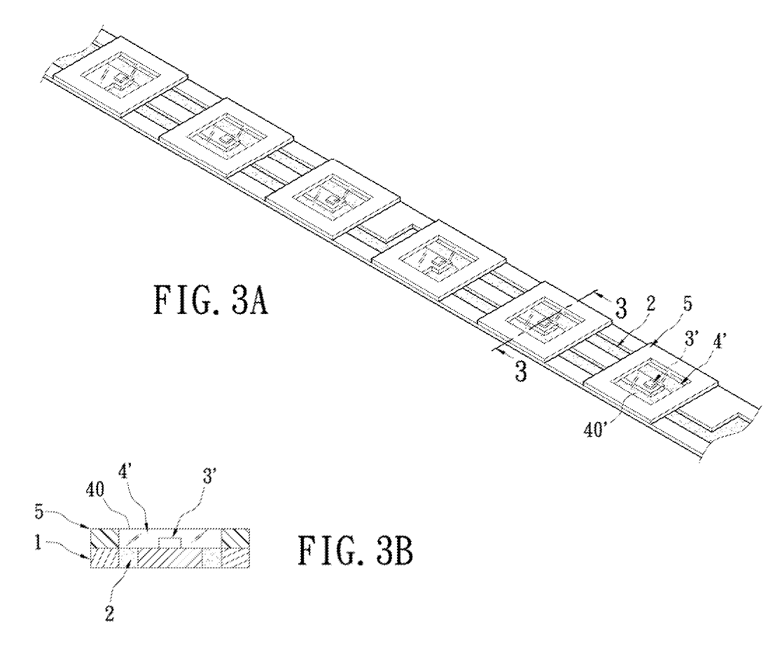

Referring to FIGS. 3, 3A and 3B, the steps S300 to S304 of the second embodiment are same as the steps S200 to S204 of the first embodiment. In other words, the illustration of S300 is the same as FIG. 2A of the first embodiment, the illustration of S302 is the same as FIG. 2B of the first embodiment, and the illustration of S304 is the same as FIG. 2C of the first embodiment.

Referring to FIGS. 3, 3A and 3B, after the step S304, the method of the second embodiment further includes: respectively covering the LED chips 3′ with a plurality of transparent bodies 4′ (S306), and then respectively disposing a plurality of frame layers 5 around the packages bodies 4′ in order to form the light-projecting surfaces 40′ on the package bodies 4′ and the light-projecting surfaces 40′ corresponding to the LED chips 3′ (S308). Moreover, each LED chip 3′ is used for generating white light, for example a red LED, a green LED and a blue LED are mated to generate white light. Each transparent body 4′ can be made of transparent silicon or transparent epoxy.

Hence, the difference between the second embodiment and the first embodiment is that: in the second embodiment, each LED chip 3′ is used for generating white light (for example a red LED, a green LED and a blue LED are mated to generate white light), so the transparent body 4′ can be transparent.

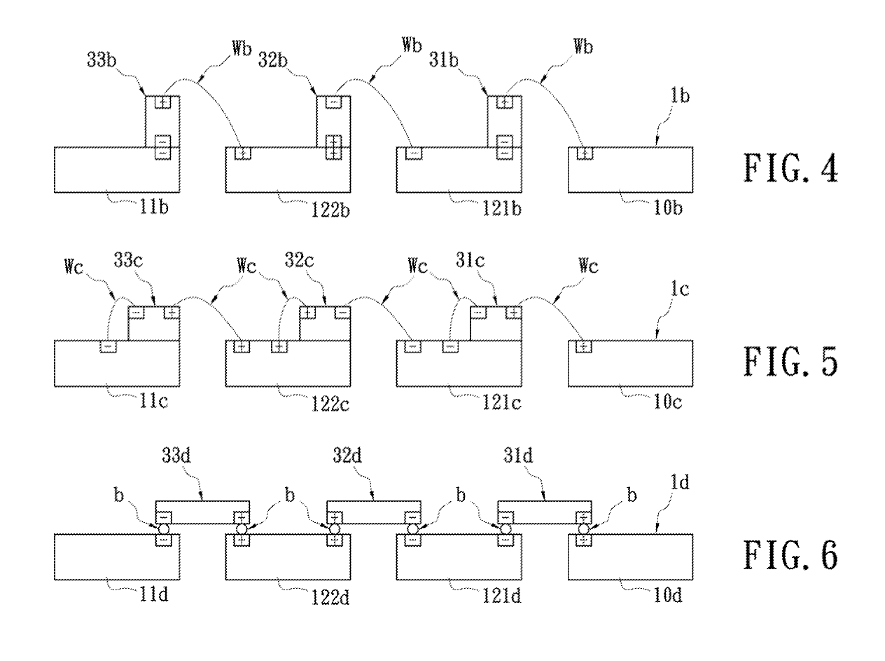

Referring to FIG. 4, a first LED chip 31b has a positive side (+) and a negative side (−) respectively formed on its top side and bottom side, a second LED chip 32b has a negative side (−) and a positive side (+) respectively formed on its top side and bottom side, and a third LED chip 33b has a positive side (+) and a negative side (−) respectively formed on its top side and bottom side.

Moreover, the first LED chip 31b is electrically connected on a first bridge substrate 121b of a substrate unit 1b. The positive side of the first LED chip 31b is electrically connected with a positive substrate 10b via a leading wire Wb, and the negative side of the first LED chip 31b is electrically connected with the first bridge substrate 121b.

The second LED chip 32b is electrically connected on a second bridge substrate 122b of the substrate unit 1b. The negative side of the second LED chip 32b is electrically connected with the first bridge substrate 121b via a leading wire Wb, and the positive side of the second LED chip 32b is electrically connected with the second bridge substrate 122b.

The third LED chip 33b is electrically connected on a negative substrate 11b of the substrate unit 1b. The positive side of the third LED chip 33b is electrically connected with the second bridge substrate 122b via a leading wire Wb, and the negative side of the third LED chip 33b is electrically connected with the negative substrate 11b.

Referring to FIG. 5, a first LED chip 31c has a positive side (+) and a negative side (−) formed on its top side, a second LED chip 32c has a negative side (−) and a positive side (+) formed on its top side, and a third LED chip 33c has a positive side (+) and a negative side (−) formed on its top side.

Moreover, the first LED chip 31c is electrically connected on a first bridge substrate 121c of a substrate unit 1c. The positive side and the negative side of the first LED chip 31c are electrically connected with a positive substrate 10c and the first bridge substrate 121c via two leading wires Wc, respectively.

The second LED chip 32c is electrically connected on a second bridge substrate 122c of the substrate unit lc. The negative side and the positive side of the second LED chip 32c are electrically connected with the first bridge substrate 121c and the second bridge substrate 122c via two leading wires Wc, respectively.

The third LED chip 33c is electrically connected on a negative substrate 11c of the substrate unit 1c. The positive side and the negative side of the third LED chip 33c are electrically connected with the second bridge substrate 122c and the negative substrate 11c via two leading wires Wc, respectively.

Referring to FIG. 6, a first LED chip 31d has a positive side (+) and a negative side (−) formed on its bottom side, a second LED chip 32d has a negative side (−) and a positive side (+) formed on its bottom side, and a third LED chip 33d has a positive side (+) and a negative side (−) respectively formed on its bottom side.

Moreover, The positive side and the negative side of the first LED chip 31d are electrically connected with a positive substrate 10d and a first bridge substrate 121d of a substrate unit 1d via two solder balls b, respectively. The negative side and the positive side of the second LED chip 32d are electrically connected with the first bridge substrate 121d and a second bridge substrate 122d of the substrate unit 1d via two solder balls b, respectively. The positive side and the negative side of the third LED chip 33d are electrically connected with the second bridge substrate 122d and a negative substrate 11c of the substrate unit 1d via two solder balls b, respectively.

Moreover, according to different needs, positive sides and negative sides of LED chips (not shown) can be electrically connected to a positive substrate and a negative substrate of a substrate unit (not shown) via parallel, serial, or parallel and serial method.

In conclusion, the LED chip package structure of the present invention has a substrate unit that is made of high heat-conducting material and is divided into a positive substrate, a negative substrate and a plurality of bridge substrates separated from each other and disposed between the positive substrate and the negative substrate. Hence, LED chips can be directly and electrically disposed on the substrate unit in order to efficiently dissipate the heat generated from the LED chips by the substrate unit.

Furthermore, because the LED chips are arranged on a substrate body by a COB (Chip On Board) method and a hot pressing method, the manufacturing process of the LED chip package structure is simple and less time is needed for the manufacturing process. Furthermore, the LED chip package structure can be applied to any type of light source such as a back light module, a decorative lamp, a lighting lamp, or a scanner.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An LED chip package structure with a high-efficiency heat-dissipating substrate, comprising:
a substrate unit having a positive substrate, a negative substrate, and a plurality of bridge substrates separated from each other and disposed between the positive substrate and the negative substrate;
an adhesive body filled between the positive substrate, the negative substrate and the bridge substrates in order to connect and fix the positive substrate, the negative substrate and the bridge substrates together;
a plurality of LED chips disposed on the substrate unit and electrically connected between the positive substrate and the negative substrate;
a plurality of package bodies respectively covering the LED chips; and
a plurality of frame layers respectively disposed around the packages bodies in order to form a plurality of light-projecting surfaces on the package bodies, wherein the light-projecting surfaces correspond to the LED chips;
wherein each package body is a transparent body, and each LED chip is used for generating white light.

2. The LED chip package structure as claimed in claim 1, wherein the substrate unit is a PCB (Printed Circuit Board), a flexible substrate, an aluminum substrate, a ceramic substrate, or a copper substrate.

3. The LED chip package structure as claimed in claim 1, wherein each LED chip has a positive side and a negative side respectively and electrically connected with the positive substrate and the negative substrate of the substrate unit via two leading wires using a wire-bounding method.

4. The LED chip package structure as claimed in claim 1, wherein the adhesive body is a heat-conducting adhesive body.

5. The LED chip package structure as claimed in claim 1, wherein each transparent body is made of transparent silicon.

6. The LED chip package structure as claimed in claim 1, wherein each transparent body is made of transparent epoxy.

7. The LED chip package structure as claimed in claim 1, wherein each frame layer is an opaque frame layer.

8. The LED chip package structure as claimed in claim 7, wherein each opaque frame layer is a white frame layer.
